(19) United States
(12) Patent Application Publication
(10) Pub. No.: US 2007/0026137 A1
(43) Pub. Date: Feb. 1, 2007

(54) Method for manufacturing electroluminescence device

(75) Inventor: Naoyuki Toyoda, Suwa (JP)

Correspondence Address: HARNESS, DICKEY & PIERCE, P.L.C., P.O. BOX 828, BLOOMFIELD HILLS, MI, 48303, US

(73) Assignee: Seiko Epson Corporation

(21) Appl. No.: 11/491,456

(22) Filed: Jul. 21, 2006

(30) Foreign Application Priority Data
Jul. 26, 2005 (JP) 2005-216344

(51) Int. Cl. B05D 5/12; B05D 3/02

(52) U.S. Cl. 427/66; 427/372.2

(57) ABSTRACT

A cathode layer, which is formed along the outer circumferential surface of a support rod, is immersed in light emitting layer forming liquid containing light emitting layer material. The cathode layer is then raised from the light emitting layer forming liquid, thus forming a light emitting liquid film with uniform thickness on the outer circumferential surface of the cathode layer. By drying the liquid film, a light emitting layer with uniform thickness is formed on the entire outer circumferential surface of the cathode layer. The light emitting layer is then immersed in hole transport layer forming liquid. This facilitates changes of the size or the shape of an electroluminescence device, improving productivity for manufacturing the electroluminescence device.

### CROSS-REFERENCE TO RELATED APPLICATION

This application is based upon and claims the benefit of priority from prior Japanese Patent Application No. 2005-216344, filed on Jul. 26, 2005, the entire contents of which are incorporated herein by reference.

### BACKGROUND OF THE INVENTION

The present invention relates to a method for manufacturing an electroluminescence device.

As typical elongated light emitting devices, fluorescent lights and neon tubes are known. A fluorescent light or a neon tube contains noble gas that is sealed in a glass tube. The fluorescent light or the neon tube emits light through discharge phenomenon caused by the noble gas. These light emitting devices are difficult to reduce in size and high in power consumption. Therefore, to solve these problems, an elongated electroluminescent device (hereinafter, referred to simply as an “EL device”) is focused on as an elongated light emitting device that is smaller in size and reduces power consumption. The EL device includes an electroluminescence element (hereinafter, an “EL element”) arranged on an outer circumferential surface of an elongated member.

A method for manufacturing an EL device is described in, for example, Japanese Laid-Open Patent Publications No. 11-265785. Specifically, the document describes a wrapping method in which a first electrode serving as a cathode, an organic layer, and a second electrode serving as an anode are sequentially deposited on a flexible sheet substrate in this order. The sheet substrate is then wrapped around a support rod. Japanese Laid-Open Patent Publication No. 2005-108643 describes a vapor deposition method in which an organic layer, a cathode, and a seal layer are sequentially vapor-deposited on an elongated anode.

However, in the wrapping method of Japanese Laid-Open Patent Publication No. 11-265785, the sheet substrate is wrapped around the support rod with an EL element, which is formed on the sheet substrate, held in a bent state. Thus, if the support rod is reduced in size, each of the layers formed in the EL element receives excessive compression stress or extension stress. This deteriorates the electric characteristics of each layer and decreases productivity for manufacturing the EL device.

In the vapor deposition method of Japanese Laid-Open Patent Publication No. 2005-108643, the layers are sequentially deposited through vapor deposition with increased directivity. Therefore, if the vapor deposition is employed to manufacture a larger-sized EL device or an EL device having a complicated shape, it is difficult to form an organic layer and a second electrode with uniform thickness. This significantly decreases productivity for manufacturing the EL device.

### SUMMARY

Accordingly, it is an objective of the present invention to provide a method for manufacturing an electroluminescence device that improves productivity for manufacturing the electroluminescence device by facilitating changes of the size and the shape of the electroluminescence device.

According to one aspect of the invention, a method for manufacturing an electroluminescence device is provided. The electroluminescence device includes a rod-shaped first electrode, an electroluminescence layer formed on an outer surface of the first electrode, and an optically transparent second electrode provided on an outer surface of the electroluminescence layer. The method includes immersing the first electrode in a first forming liquid containing a material of the electroluminescence layer. A first liquid film made of the first forming liquid is formed on the outer surface of the first electrode by raising the first electrode from the first forming liquid. The electroluminescence layer is formed by drying the first liquid film.

Other aspects and advantages of the invention will become apparent from the following description, taken in conjunction with the accompanying drawings, illustrating by way of example the principles of the invention.

### BRIEF DESCRIPTION OF THE DRAWINGS

The invention, together with objects and advantages thereof, may best be understood by reference to the following description of the presently preferred embodiments together with the accompanying drawings in which:

FIG. 1 is a perspective view showing an electroluminescence device manufactured by a method according to the present invention;

FIG. 2 is a cross-sectional view showing the electroluminescence device of FIG. 1 taken along line A-A;

FIG. 3 is a cross-sectional view for explaining a method for manufacturing the electroluminescence device of FIG. 1, showing a support rod that is being raised from cathode forming liquid;

FIG. 4 is a cross-sectional view showing a cathode layer formed on an outer circumferential surface of the support rod;

FIG. 5 is a cross-sectional view showing the cathode layer that is being raised from light emitting layer forming liquid;

FIG. 6 is a cross-sectional view showing the light emitting layer formed on an outer circumferential surface of the cathode layer;

FIG. 7 is a cross-sectional view showing the light emitting layer that is being raised from hole transport layer forming liquid;

FIG. 8 is a cross-sectional view showing the hole transport layer formed on an outer circumferential surface of the light emitting layer;

FIG. 9 is a cross-sectional view showing the hole transport layer that is being raised from anode forming liquid; and

FIG. 10 is a cross-sectional view showing an anode layer formed on an outer circumferential surface of the hole transport layer.

### DETAILED DESCRIPTION OF THE PREFERRED EMBODIMENTS

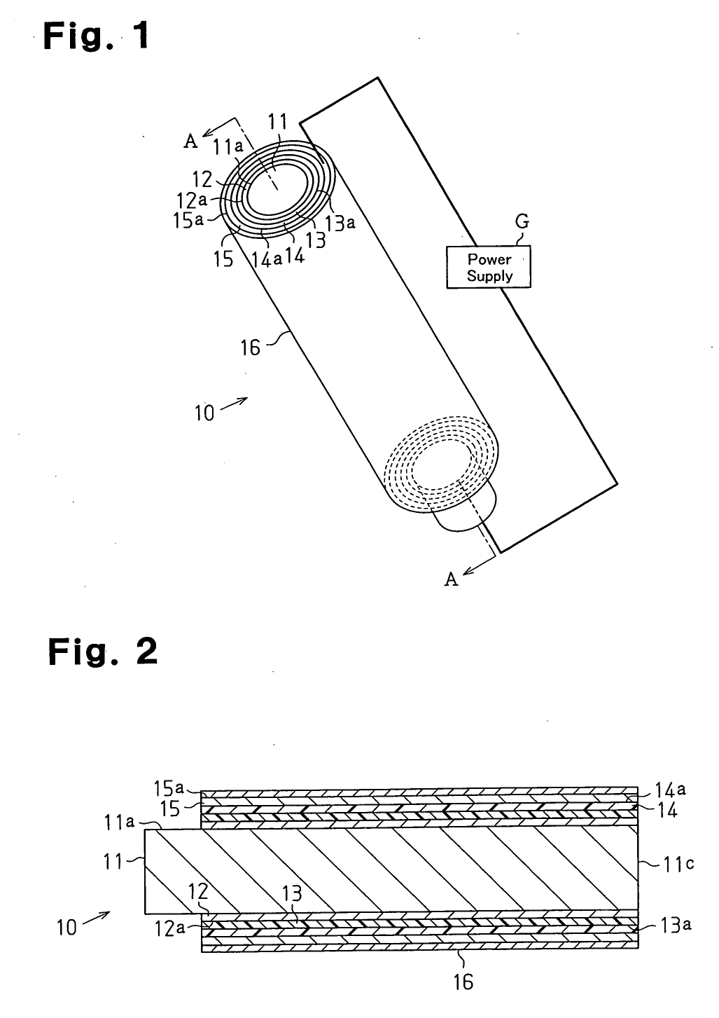

An embodiment of the present invention will now be described with reference to FIGS. 1 to 10.

As shown in FIG. 1, an electroluminescence device (hereinafter, referred to simply as an “EL device”) 10 includes a substantially columnar support rod 11 formed of insulating material. Specifically, the support rod 11 is formed of, for example, inorganic material including different types of glasses or flexible resin material including polyethylene terephthalate, polyethylene naphthalate, polypropylene, and polymethylmethacrylate. In the illustrated embodiment, the diameter of the support rod 11 is approximately 5 nm and the length of the support rod 11 is approximately 200 nm. However, the size of the support rod 11 may be selected in any other suitable manner as long as different liquid films, which will be explained later, can be formed on an outer circumferential surface 11a of the support rod 11.

A cathode layer 12, or a first electrode, is formed on the outer circumferential surface 11a, or an outer surface, of the support rod 11. The cathode layer 12 is a cathode having uniform thickness formed on the entire outer circumferential surface 11a. The cathode layer 12 is formed of conductive material with relatively small work function (cathode material: metal elementary substances such as Li, Mg, Ca, Sr, La, Ce, Er, Eu, Sc, Y, Yb, Ag, Cu, Al, Cs, and Rb). The cathode layer 12 is electrically connected to the negative electrode of a power supply G, which supplies drive power to the EL device 10. The cathode layer 12 thus injects electrons into a light emitting layer 13, which will be described later. To improve stability of the cathode material, the material may be selected as alloy types containing two or three elements of the above-described list. If alloy type material is employed, it is preferred that alloy containing stable metal elements such as Ag, Al, and Cu, or, more specifically, alloys such as MgAg, AlLi, or CuLi, be selected. These alloys improve electron injection efficiency and stability of the cathode layer 12.

The light emitting layer 13, which forms a part of an electroluminescence layer (hereinafter, referred to simply as an “EL layer”), is arranged on an outer circumferential surface 12a, or an outer surface, of the cathode layer 12. The light emitting layer 13 is an organic layer with uniform thickness formed on the entire outer circumferential surface 12a of the cathode layer 12. The thickness of the light emitting layer 13 is not restricted to a particular range. However, the thickness of the light emitting layer 13 is preferably 10-150 nm, and, more preferably, to 50-100 nm. If the thickness of the light emitting layer 13 falls in these ranges, recombining of holes and electrons is efficiently brought about. This increases light emitting efficiency of the light emitting layer 13. The light emitting layer 13 is formed of light emitting layer material that injects electrons from the cathode layer 12 and holes from an anode layer 15, which will be explained later, when voltage is applied between the cathode layer 12 and the anode layer 15. When the holes and the electrons recombine and thus release energy, the energy causes the light emitting layer 13 to generate excitons (excitation elements). When the excitons restore the ground state, the released energy emits fluorescence or phosphorescence.

In the illustrated embodiment, the light emitting layer material is fluorene-dithiophene copolymer (hereinafter, referred to simply as “F8T2”). However, the present invention is not restricted to this. The materials listed below may be employed as the light emitting layer material of the present invention independently or in combination of two or more materials. The listed materials include different types of known low-molecular materials and high molecular materials.

The low-molecular light emitting layer materials include, for example, cyclopentadiene derivatives, tetraphenylbutadiene derivatives, triphenylamine derivatives, oxadiazole derivatives, distyrylbenzene derivatives, thiophene cyclic compounds, pirydine cyclic compounds, perynone derivatives, perylene derivatives, coumarin derivatives, and metal complexes such as aluminum quinolinol complexes, benzoquinolinol berylium complexes, benzoxazole zinc complexes, benzothiazole zinc complexes, azomethyl zinc complexes, porphyrin zinc complexes, and europium complexes.

The high molecular light emitting layer materials include, for example, polyparaphenylene vinylene derivatives, polyparaphenylene derivatives, polysilane derivatives, polyacetylene derivatives, polythiophene derivatives, polyvinyl carbazol, polyfluorenone derivatives, polyquinoxaline derivatives, polyvinylene stylene derivatives, copolymers formed from these derivatives, and different types of dendrimers including triphenylamine or ethylenediamine as molecular nuclei.

A hole transport layer 14, which forms a part of the EL layer, is formed on an outer surface (an outer circumferential surface 13a) of the light emitting layer 13. The hole transport layer 14 is an organic layer with uniform thickness formed on the entire outer circumferential surface 13a. In the illustrated embodiment, the thickness of the hole transport layer 14 is not particularly specified. However, if the thickness of the hole transport layer 14 is excessively small, a pin hole may be formed. If the thickness of the hole transport layer 14 is excessively great, permeability of the hole transport layer 14 may decrease and change chromaticity (hue) of the light emitted by the light emitting layer 13. Therefore, the thickness of the hole transport layer 14 is preferably 10-150 nm, and, more preferably, 50-100 nm. The hole transport layer material that forms the hole transport layer 14 is formed of a conjugated organic compound. Through the property of the material in terms of the presence of electron clouds, the hole transport layer 14 transports holes injected by the anode layer 15, which will be described later, to the light emitting layer 13.

In the illustrated embodiment, the hole transport layer material is defined by poly(3,4-ethylene dioxythiophene) (hereinafter, referred to simply as “PEDOT”). However, the materials listed below may be employed as the hole transport layer material of the present invention independently or in combination of two or more materials. The listed materials include different types of low-molecular or high molecular hole transport layer materials.

The low-molecular hole transport layer materials include, for example, benzidine derivatives, triphenylmethane derivatives, phenylenediamine derivatives, styrylamine derivatives, hydrazone derivatives, pyrazoline derivatives, carbazole derivatives, and porphyrin compounds.

The high molecular hole transport layer materials include high molecular compounds containing any of the above-listed molecular structures (as a main chain or a side chain), polyaniline, polythiophenevinylene, polythiophene, α-naphthylphenyldiamine, mixtures of “PEDOT” and polystyrene sulfonate (Baytron P, trade mark of Bayer Corporation), and different types of dendrimers containing triphenylamine or ethylenediamine as molecular nuclei.

If any of the above-listed low-molecular hole transport layer materials is employed, binder (high molecular binder) may be added to the material as necessary. In this case, it is preferable to select binder that does not excessively suppress charge transport and exhibits relatively low absorption rate of visible lights. Specifically, as the binder, one or more substances selected from polyethylene oxide, polyvinylidene fluoride, polycarbonate, polyacrylate, polymethyl acrylate, polymethyl methacrylate, polystyrene, polyvinyl chloride, and polyciloxane may be employed independently or in combination. Alternatively, any of the above-listed high molecular hole transport layer materials may be selected as the binder.

The anode layer 15, or a first electrode, is formed on an outer circumferential surface 14a, or an outer surface, of the hole transport layer 14. The anode layer 15 is defined by an optically transparent anode with uniform thickness formed on the entire outer circumferential surface 14a. The anode layer 15 is formed of conductive material having relatively great work function (anode material: for example, inorganic oxides including ITO (indium tin oxide), SnO₂, SnO₂ containing Sb, and ZnO containing Al or transparent conductive resin including polythiophene and polypyrrole). The anode layer 15 is electrically connected to the positive electrode of the power supply G and thus injects holes into the hole transport layer 14.

A seal layer 16 is formed on an outer circumferential surface 15a, or an outer surface, of the anode layer 15 in such a manner as to entirely cover the outer circumferential surface 15a. The seal layer 16 is defined by an optically transparent, inorganic or organic high molecular film having a gas barrier property. The seal layer 16 thus prevents water or oxygen from entering the hole transport layer 14 or the light emitting layer 13.

When the power supply G is turned on and voltage is applied between the anode layer 15 and the cathode layer 12, electrons move from the cathode layer 12 to the light emitting layer 13 and holes move from the anode layer 15 to the light emitting layer 13 through the hole transport layer 14. The holes and the electrons recombine in the light emitting layer 13, releasing energy. The light emitting layer 13 thus generates excitons (excitation element) through the energy. The light emitting layer 13 emits light through transition of the excitons to the ground state.

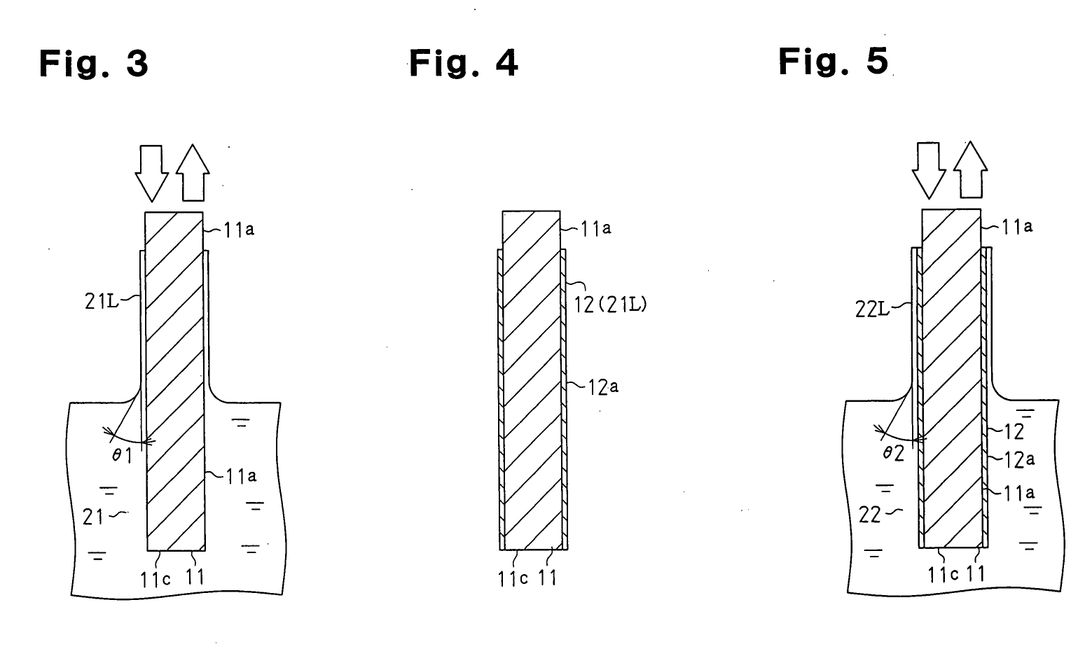

Next, a method for manufacturing the EL device 10 will be described with reference to FIGS. 3 to 10.

First, a cathode forming step is performed for forming the cathode layer 12 on the outer circumferential surface 11a of the support rod 11. Specifically, as illustrated in FIG. 3, the outer circumferential surface 11a of the support rod 11 is entirely immersed in cathode forming liquid 21, or first electrode forming liquid. In the illustrated embodiment, the cathode forming liquid 21 is a liquid prepared by dispersing silver nanoparticles of the aforementioned cathode material in organic type dispersion medium. In order to facilitate formation of a cathode liquid film 21L, which will be described later, it is preferred that the receding contact angle θ1 of the cathode forming liquid 21 be adjusted to 45 degrees or smaller with respect to the outer circumferential surface 11a.

Afterwards, the support rod 11 is gradually raised from the cathode forming liquid 21. The cathode liquid film 21L made of the cathode forming liquid 21 is thus formed on the entire outer circumferential surface 11a of the support rod 11. The thickness of the cathode liquid film 21L is determined in correspondence with the receding contact angle θ1 and becomes uniform over a substantially entire portion of the outer circumferential surface 11a of the support rod 11. When the support rod 11 is raised and removed from the cathode forming liquid 21, the thickness of a portion of the cathode liquid film 21L formed on a bottom surface 11c, an end surface facing the cathode forming liquid 21 of the support rod 11, may become non-uniform compared to the thickness of a portion of the cathode liquid film 21L formed on the outer circumferential surface 11a. Therefore, in the illustrated embodiment, the portion of the cathode liquid film 21L formed on the bottom surface 11c is wiped off from the bottom surface 11c. However, alternatively, the bottom surface 11c may be formed as a semispherical surface in such a manner that the portion of the cathode liquid film 21L formed on the bottom surface 11c becomes uniform with respect to the other portion of the cathode liquid film 21L.

After formation of the cathode liquid film 21L is completed, the support rod 11 is transported to a drying-baking furnace. The support rod 11 is thus heated to a predetermined drying temperature and a predetermined baking temperature that are selected in correspondence with the cathode forming liquid 21. The cathode liquid film 21L is thus dried and baked. In this manner, referring to FIG. 4, the cathode layer 12 with the uniform thickness is formed on the entire outer circumferential surface 11a of the support rod 11, regardless of modification, if any, of the outer diameter or the length or the shape of the support rod 11.

If the thickness of the cathode layer 12 is less than a predetermined level at this stage, the above-described immersion, raising, and drying-baking of the support rod 11 may be repeated in order to increase the thickness of the cathode layer 12. Alternatively, the solvent or the dispersion medium of the cathode forming liquid 21 may be modified in such a manner as to decrease the receding contact angle θ1, thus increasing the thickness of the cathode liquid film 21L. Contrastingly, if the thickness of the cathode layer 12 exceeds the predetermined level after the immersion, the raising, and the drying-baking of the support rod 11, pressurized air may be blasted onto the entire support rod 11 (the entire outer circumferential surface 11a). This decreases the thickness of the cathode liquid film 21L. Alternatively, the solvent or the dispersion medium of the cathode forming liquid 21 may be changed in such a manner as to increase the receding contact angle θ1, thus reducing the thickness of the cathode liquid film 21L.

Following the cathode forming step, a light emitting layer forming step is carried out for providing the light emitting layer 13 on the cathode layer 12 (the outer circumferential surface 12a). Specifically, as illustrated in FIG. 5, the outer circumferential surface 12a of the cathode layer 12, which has been formed on the support rod 11, is entirely immersed in light emitting layer forming liquid 22, which is an element contained in electroluminescence layer forming liquid. In the illustrated embodiment, the light emitting layer forming liquid 22 is a liquid prepared by dissolving the aforementioned light emitting material “F8T2” in nonpolar organic solvent (such as benzene, toluene, xylene, cyclohexyl benzene, dihydrobenzofuran, trimethyl benzene, or tetramethyl benzene). However, instead of this, the light emitting layer forming liquid 22 may be a liquid formed of any of the above-described low-molecular light emitting layer materials and organic or inorganic solvent or dispersion medium that is selected in correspondence with the light emitting layer material to be employed. In order to facilitate formation of a light emitting liquid film 22L, which will be described later, it is preferred that the receding contact angle θ2 of the light emitting layer forming liquid 22 be 45 degrees or smaller with respect to the outer circumferential surface 12a of the cathode layer 12.

Afterwards, the outer circumferential surface 12a of the cathode layer 12 is gradually raised from the light emitting layer forming liquid 22. This provides the light emitting liquid film 22L formed of the light emitting layer forming liquid 22 on the entire outer circumferential surface 12a. The thickness of the light emitting liquid film 22L is determined in correspondence with the receding contact angle θ2 and becomes uniform along a substantially entire portion of the cathode layer 12 (the outer circumferential surface 12a). In the illustrated embodiment, a portion of the light emitting liquid film 22L is wiped off from the bottom surface 11c of the support rod 11, as in the cathode forming step. However, instead of this, the shape of the bottom surface 11c may be modified in such a manner that the portion of the light emitting liquid film 22L formed on the bottom surface 1c becomes uniform with respect to the other portion of the light emitting liquid film 22L.

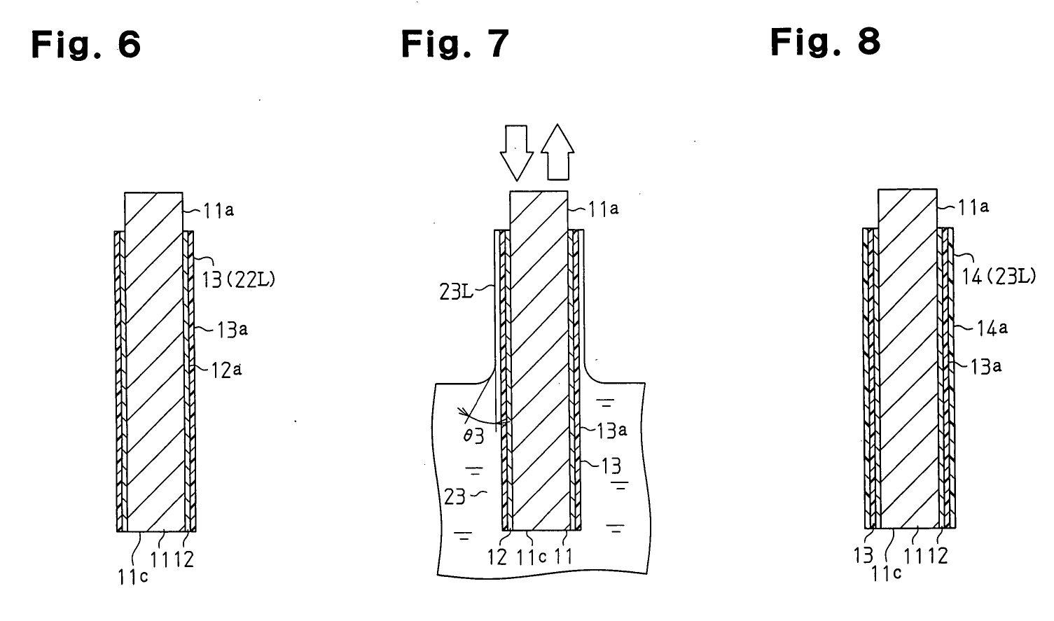

After completion of the light emitting liquid film 22L, the support rod 11 is transported to a drying furnace and thus heated to a predetermined drying temperature selected in correspondence with the light emitting layer forming liquid 22. The light emitting liquid film 22L thus becomes dry. In this manner, with reference to FIG. 6, the light emitting layer 13 with uniform thickness is formed on the entire cathode layer 12 (the entire outer circumferential surface 12a), regardless of modification, if any, of the outer diameter or the length or the shape of the support rod 11.

If the thickness of the light emitting layer 13 is less than a predetermined level at this stage, immersion, raising, and drying of the support rod 11 may be repeated in the same manner as the above-described operation so as to increase the thickness of the light emitting layer 13. Alternatively, the solvent or the dispersion medium of the light emitting layer forming liquid 22 may be altered in such a manner as to decrease the receding contact angle θ2, thus increasing the thickness of the light emitting liquid film 22L. Contrastingly, if the thickness of the light emitting layer 13 exceeds the predetermined level after the immersion, the raising, and the drying of the support rod 11, pressurized air may be blasted onto the entire cathode layer 12 (the entire outer circumferential surface 12a). This decreases the thickness of the light emitting liquid film 22L. Alternatively, the solvent or the dispersion medium of the light emitting layer forming liquid 22 may be changed in such a manner as to increase the receding contact angle θ2. The thickness of the light emitting liquid film 22L thus decreases.

Following the light emitting layer forming step, a hole transport layer forming step is performed to provide the hole transport layer 14 on the light emitting layer 13 (the outer circumferential surface 13a). Specifically, as illustrated in FIG. 7, the outer circumferential surface 13a of the light emitting layer 13, which has been formed on the support rod 11, is entirely immersed in hole transport layer forming liquid 23. In the illustrated embodiment, the hole transport layer forming liquid 23 is prepared by dissolving the aforementioned hole transport layer material “PEDOT” in water type solvent (for example, water, lower alcohol such as mathanol, or cellosolve type solvent such as etoxyethanol). However, instead of this, the hole transport layer forming liquid 23 may be changed to liquid containing any of the above-described low-molecular hole transport layer materials and organic or inorganic solvent or dispersion medium that is selected in correspondence with the hole transport layer material to be employed. In order to facilitate formation of a hole transport liquid film 23L, which will be described later, it is preferred that the receding contact angle θ3 of the hole transport layer forming liquid 23 be 45 degrees or smaller with respect to the outer circumferential surface 13a of the light emitting layer 13.

Afterwards, the outer circumferential surface 13a of the light emitting layer 13 is gradually raised from the hole transport layer forming liquid 23. This provides the hole transport liquid film 23L formed of the hole transport layer forming liquid 23 on the entire outer circumferential surface 13a. The thickness of the hole transport liquid film 23L is determined in correspondence with the receding contact angle θ3 and becomes uniform along a substantially entire portion of the light emitting layer 13 (the outer circumferential surface 13a). In the illustrated embodiment, a portion of the hole transport liquid film 23L is wiped off from the bottom surface 11c of the support rod 11, as in the cathode forming step. However, instead of this, the shape of the bottom surface 11c may be modified in such a manner that the portion of the hole transport liquid film 23L formed on the bottom surface 11c becomes uniform with respect to the other portion of the hole transport liquid film 23L.

After completion of the hole transport liquid film 23L, the support rod 11 is transported to a drying furnace. The support rod 11 is thus heated to a predetermined drying temperature that is selected in correspondence with the hole transport layer forming liquid 23, thus drying the hole transport liquid film 23L. In this manner, referring to FIG. 8, the hole transport layer 14 with uniform thickness is formed on the entire light emitting layer 13 (the entire outer circumferential surface 13a), regardless of modification, if any, of the outer diameter or the length or the shape of the support rod 11.

If the thickness of the obtained hole transport layer 14 is less than a predetermined level, the above-described operation including immersion, raising, and drying of the support rod 11 may be repeated so as to increase the thickness of the hole transport layer 14. Alternatively, the solvent or the dispersion medium of the hole transport layer forming liquid 23 may be altered in such a manner as to decrease the receding contact angle θ3, thus increasing the thickness of the hole transport liquid film 23L. Contrastingly, if the thickness of the hole transport layer 14 exceeds the predetermined level after the immersion, the raising, and the drying of the support rod 11, pressurized air may be blasted onto the entire light emitting layer 13 (the entire outer circumferential surface 13a), thus decreasing the thickness of the hole transport liquid film 23L. Alternatively, the solvent or the dispersion medium of the hole transport layer forming liquid 23 may be altered in such a manner as to increase the receding contact angle θ3. This decreases the thickness of the hole transport liquid film 23L.

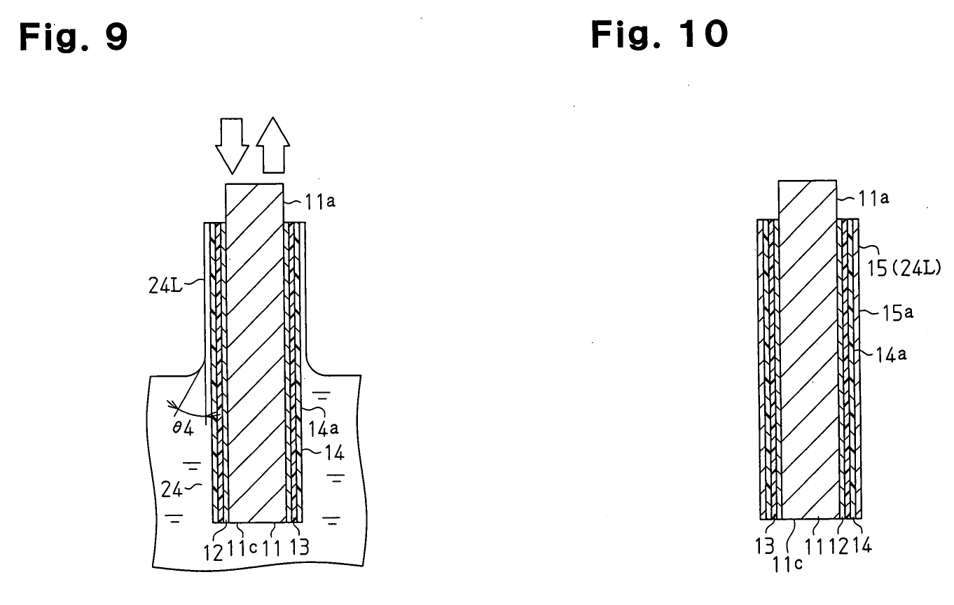

The hole transport layer forming step is followed by an anode forming step in which the anode layer 15 is formed on the hole transport layer 14 (the outer circumferential surface 14a). That is, with reference to FIG. 9, the outer circumferential surface 14a of the hole transport layer 14, which has been formed on the support rod 11, is entirely immersed in anode forming liquid 24. In the illustrated embodiment, the anode forming liquid 24 is a liquid prepared by dispersing ITO nanoparticles of the aforementioned anode material in organic dispersion medium. In order to facilitate formation of an anode liquid film 24L, which will be explained later, it is preferred that the receding contact angle θ4 of the anode forming liquid 24 be 45 degrees or smaller with respect to the outer circumferential surface 14a.

Afterwards, the support rod 11 is gradually raised from the anode forming liquid 24. In this manner, the anode liquid film 24L formed of the anode forming liquid 24 is formed on the entire outer circumferential surface 14a. The thickness of the anode liquid film 24L is determined in correspondence with the receding contact angle θ4 and becomes uniform along a substantially entire portion of the hole transport layer 14 (the outer circumferential surface 14a). In the illustrated embodiment, a portion of the anode liquid film 24L formed on the bottom surface 11c of the support rod 11 is wiped off from the bottom surface 11c as in the cathode forming step. However, instead of this, the bottom surface 11c may be differently shaped in such a manner that the portion of the anode liquid film 24L formed on the bottom surface 11c becomes uniform with respect to the other portion of the anode liquid film 24L.

After forming the anode liquid film 24L, the support rod 11 is transported to a drying-baking furnace. The support rod 11 is thus heated to a predetermined drying temperature and then to a baking temperature. These temperatures are selected in correspondence with the anode forming liquid 24. The anode liquid film 24L is thus dried and baked. Accordingly, the anode layer 15 with uniform thickness is formed on the entire hole transport layer 14 (the entire outer circumferential surface 14a), regardless of modification, if any, of the outer diameter or the length or the shape of the support rod 11.

If the thickness of the obtained anode layer 15 is less than a predetermined level, the above-described immersion and raising of the support rod 11 in the anode forming liquid 24 and the drying-baking of the support rod 11 may be repeated to increases the thickness of the anode layer 15. Alternatively, the solvent or the dispersion medium of the anode forming liquid 24 may be altered in such a manner as to decrease the receding contact angle θ4, thus increasing the thickness of the anode liquid film 24L. Contrastingly, if the thickness of the anode layer 15 exceeds the predetermined level after the immersion, the raising, and the drying-baking of the support rod 11, pressurized air may be blasted onto the entire outer circumferential surface 15a while the support rod 11 is being raised from the anode forming liquid 24. This decreases the thickness of the anode liquid film 24L. Alternatively, by changing the solvent or the dispersion medium of the anode forming liquid 24 in such a manner as to increase the receding contact angle θ4, the thickness of the anode liquid film 24L may be decreased.

After completion of the anode forming step, a seal layer forming step is carried out to form the seal layer 16 on the anode layer 15. Specifically, the seal layer 16 is applied onto and thus formed on the entire support rod 11 on which the cathode layer 12, the light emitting layer 13, the hole transport layer 14, and the anode layer 15 have been provided. The seal layer 16 has the gas barrier property and is defined by the inorganic or organic high molecular film. When applying the seal layer 16 onto the support rod 11, a portion of the cathode layer 12 and a portion of the anode layer 15 are masked. This provides a non-illustrated connection area in each of the masked portions through which the cathode layer 12 or the anode layer 15 is connected to the power supply G.

Accordingly, the cathode layer 12, the light emitting layer 13, the hole transport layer 14, the anode layer 15, and the seal layer 16 are all formed with uniform thicknesses on the entire support rod 11 (the entire outer circumferential surface 11a) in accordance with modification of the outer diameter or the length or the shape of the support rod 11.

The illustrated embodiment has the following advantages.

(1) In the illustrated embodiment, the outer circumferential surface 12a of the cathode layer 12, which is formed on the outer circumferential surface 11a of the support rod 11, is immersed in the light emitting layer forming liquid 22 containing the light emitting layer material. The support rod 11 is then removed from the light emitting layer forming liquid 22, and the light emitting liquid film 22L having the uniform thickness is formed on the outer circumferential surface 12a of the cathode layer 12. The light emitting liquid film 22L is then dried to form the light emitting layer 13 with the uniform thickness on the entire outer circumferential surface 12a of the cathode layer 12. Further, the outer circumferential surface 13a of the light emitting layer 13 is immersed in the hole transport layer forming liquid 23 containing the hole transport layer material. The outer circumferential surface 13a of the light emitting layer 13 is then raised from the hole transport layer forming liquid 23, with the hole transport liquid film 23L having the uniform thickness formed on the outer circumferential surface 13a of the light emitting layer 13. Subsequently, the hole transport liquid film 23L is dried to form the hole transport layer 14 having the uniform thickness on the entire outer circumferential surface 13a of the light emitting layer 13.

That is, the light emitting layer 13 and the hole transport layer 14 are obtained through the above-described immersion and raising of the support rod 11 with respect to the light emitting layer forming liquid 22 and the hole transport layer forming liquid 23, respectively. When complete, the light emitting layer 13 and the hole transport layer 14 each have the uniform thickness corresponding to the outer diameter or the length of the support rod 11. This facilitates changes of the size or the shape of the support rod 11 and thus increases productivity for manufacturing the EL device 10.

(2) In the illustrated embodiment, the cathode liquid film 21L and the anode liquid film 24L are formed through the above-described immersion and raising of the support rod 11 with respect to the cathode forming liquid 21 and the anode forming liquid 24, respectively. Then, the cathode layer 12 and the anode layer 15 are provided through drying-baking of the cathode liquid film 21L and the anode liquid film 24L, respectively.

In other words, the cathode layer 12 and the anode layer 15 are obtained through the immersion and raising of the support rod 11 with respect to the cathode forming liquid 21 and the anode forming liquid 24, respectively. When complete, the cathode layer 12 and the anode layer 15 each have the uniform thickness corresponding to the outer diameter or the length of the support rod 11. This facilitates changes of the size or the shape of the support rod 11 and thus improves the productivity for manufacturing the EL device 10.

(3) In the illustrated embodiment, the seal layer 16 is formed on the outer circumferential surface 15a of the anode layer 15. This prevents water or oxygen from entering the light emitting layer 13 and the hole transport layer 14, suppressing deterioration of the light emitting layer 13 and the hole transport layer 14.

The illustrated embodiment may be modified as follows.

In the illustrated embodiment, the support rod 11 has a circular cross-sectional shape and an elongated outline. However, the support rod 11 may have an oval or rectangular cross-sectional shape or a spirally curved outline.

Although the support rod 11 is formed of insulating material in the illustrated embodiment, the support rod 11 may be formed of conductive material, or cathode forming material. This makes it unnecessary to separately provide the cathode layer 12 on the outer circumferential surface 11a of the support rod 11. The cathode forming step can thus be omitted. Further, the productivity for manufacturing the EL device 10 improves.

In the illustrated embodiment, the anode layer 15 is formed of the anode forming liquid 24 containing the ITO nanoparticles. However, instead of this, the anode forming liquid 24 may be, for example, a mixture of indium nitrate and anhydrous stannic chloride with n-butyl carbitol as solvent. The anode layer 15 is thus formed of ITO. Alternatively, paste of tin oxide or indium oxide may be applied onto and dried on the outer circumferential surface 14a of the hole transport layer 14, thus providing the anode layer 15 formed of tin oxide or indium oxide.

In the illustrated embodiment, the cathode layer 12 and the anode layer 15 are formed through immersion and removal of the support rod 11 with respect to the cathode forming liquid 21 and the anode forming liquid 24, respectively. However, the cathode layer 12 and the anode layer 15 may be formed through vapor deposition.

In the illustrated embodiment, the cathode layer 12, the light emitting layer 13, the hole transport layer 14, and the anode layer 15 are arranged on the outer circumferential surface 11a of the support rod 11 in this order. However, the anode layer 15, the light emitting layer 13, the hole transport layer 14, and the cathode layer 12 may be formed on the outer circumferential surface 11a of the support rod 11 in this order. The cathode layer 12, which is optically transparent, is formed on the outer circumferential surface 13a of the light emitting layer 13. In this case, the anode layer 15 may be formed using metal such as gold, platinum, palladium, or nickel or a semiconductor with a relatively great work function such as silicon, gallium-phosphorus, or amorphous silicon carbide. The listed materials may be used independently or in combination of two or more materials, as the material of the anode layer 15. Alternatively, the anode layer 15 may be formed of conductive resin material such as polythiophene or polypyrrol.

In the illustrated embodiment, the light emitting material is an organic high molecular material or an organic low-molecular material. However, the light emitting layer 13 may be formed of an inorganic molecular substance such as ZnS/CuCl, ZnS/CuBr, or ZnCdS/CuBr. In this case, it is preferred that the light emitting layer forming liquid 22 be prepared by dispersing the light emitting layer material in organic binder. The organic binder may be defined by cyanoethylate of polysaccharide such as cyanoethyl cellulose, cyanoethyl starch, or cyanoethyl pullulan or cyanoetylate of a polysaccharide derivative such as cyanoethyl hydroxyethyl cellulose or cyanoethyl glyserol pullulan or cyanoethylate of polyol such as cyanoethyl polyvinyl alcohol.

In the illustrated embodiment, the single light emitting layer 13 is formed on the outer circumferential surface 12a of the cathode layer 12. However, instead of this, a multi-photon structure may be employed. That is, a plurality of units each including the light emitting layer 13 and a charge generating layer may be provided between the cathode layer 12 and the anode layer 15.

The anode layer 15 is formed on the outer circumferential surface 14a of the hole transport layer 14. However, for example, the hole transport layer 14 may be omitted. Alternatively, a hole injection layer may be provided between the anode layer 15 and the hole transport layer 14. The hole injection layer improves efficiency for injecting holes into the light emitting layer 13.

In the illustrated embodiment, the hole transport layer 14 is formed on the outer circumferential surface 13a of the light emitting layer 13. However, for example, an electron barrier layer may be formed between the hole transport layer 14 and the light emitting layer 13. The electron barrier layer suppresses movement of electrons.

In the illustrated embodiment, the light emitting layer 13 is formed on the outer circumferential surface 12a of the cathode layer 12. However, for example, an electron transport layer may be formed between the light emitting layer 13 and the cathode layer 12. The electron transport layer transports the electrons from the cathode layer 12 to the light emitting layer 13. Further, a hole barrier layer may be arranged between the light emitting layer 13 and the electron transport layer, thus suppressing movement of holes.

The present examples and embodiments are to be considered as illustrative and not restrictive and the invention is not to be limited to the details given herein, but may be modified within the scope and equivalence of the appended claims.

1. A method for manufacturing an electroluminescence device including a rod-shaped first electrode, an electroluminescence layer formed on an outer surface of the first electrode, and an optically transparent second electrode provided on an outer surface of the electroluminescence layer, wherein the method comprises:
immersing the first electrode in a first forming liquid containing a material of the electroluminescence layer;
forming a first liquid film made of the first forming liquid on the outer surface of the first electrode by raising the first electrode from the first forming liquid; and
forming the electroluminescence layer by drying the first liquid film.

2. The method according to claim 1, further comprising:
immersing the electroluminescence layer in a second forming liquid containing a material of the second electrode;
forming a second liquid film made of the second forming liquid on the outer surface of the electroluminescence layer by raising the electroluminescence layer from the second forming liquid; and
forming the second electrode by drying the second liquid film.

3. The method according to claim 1, further comprising:
immersing a support rod in a third forming liquid containing a material of the first electrode;
forming a third liquid film made of the third forming liquid on an outer surface of the support rod by raising the support rod from the third forming liquid; and
forming the first electrode by drying the third electrode film.

4. The method according to claim 1, further comprising forming a seal layer on an outer surface of the second electrode for preventing atmospheric air from entering the electroluminescence layer.

5. The method according to claim 1, further comprising setting a receding contact angle of the first forming liquid with respect to the outer surface of the first electrode when the first electrode is raised from the first forming liquid to 45 degrees or smaller.

6. The method according to claim 1, wherein the electroluminescence layer includes a light emitting layer formed on the outer surface of the first electrode and a hole transport layer formed on an outer surface of the light emitting layer, the method further comprising:
immersing the first electrode in a fourth forming liquid containing a material of the light emitting layer;
forming a fourth liquid film made of the fourth forming liquid on the outer surface of the first electrode by raising the first electrode from the fourth forming liquid;
forming the light emitting layer by drying the fourth liquid film;
immersing the light emitting layer in a fifth forming liquid containing a material of the hole transport layer;
forming a fifth liquid film made of the fifth forming liquid on the outer surface of the light emitting layer by raising the light emitting layer from the fifth forming liquid; and
forming the hole transport layer by drying the fifth liquid film.

7. The method according to claim 1, wherein the electroluminescence layer includes a hole transport layer formed on the outer surface of the first electrode and a light emitting layer formed on an outer surface of the hole transport layer, the method further comprising:
immersing the first electrode in a fifth forming liquid containing a material of the hole transport layer;
forming a fifth liquid film made of the fifth forming liquid on the outer surface of the first electrode by raising the first electrode from the fifth forming liquid;
forming the hole transport layer by drying the fifth liquid film;
immersing the hole transport layer in a fourth forming liquid containing a material of the light emitting layer;
forming a fourth liquid film made of the fourth forming liquid on the hole transport layer by raising the hole transport layer from the fourth forming liquid; and
forming the light emitting layer by drying the fourth liquid film.
